(19) United States
(12) Patent Application Publication
(10) Pub. No.: US 2012/0302049 A1
(43) Pub. Date: Nov. 29, 2012

(54) METHOD FOR IMPLANTING WAFER

(75) Inventors: Ping Hsu, Taoyuan County (TW); Yi-Nan Chen, Taoyuan County (TW); Hsien-Wen Liu, Taoyuan County (TW)

(73) Assignee: NANYA TECHNOLOGY CORPORATION, TAOYUAN (TW)

(21) Appl. No.: 13/115,030

(22) Filed: May 24, 2011

(51) Int. Cl. H01L 21/265

(52) U.S. Cl. 438/514; 257/E21.334

(57) ABSTRACT

The disclosure provides a method for wafer implantation including the following steps: providing a wafer, wherein the wafer comprises a central circular portion, and a peripheral annular portion adjacent to a edge of the wafer, and wherein the central circular portion and the peripheral annular portion are concentric; and implanting ion beams into the wafer, wherein the central circular portion has a first average implantation dose and the peripheral annular portion has a second average implantation dose, and the first average implantation dose and the second first average implantation dose are different.

### BACKGROUND

1. Technical Field

The present invention relates to a method for manufacturing a semiconductor device. More specifically, the present invention relates to an ion implantation method for manufacturing semiconductors.

2. Description of the Related Art

In order to manufacture semiconductor devices, in particular semiconductor memory devices such as dynamic random access memories (DRAMs), numerous processes are carried out. Such processes include laminating, etching, ion implantation, etc., and are usually conducted on the base of a wafer unit. Among the unit processes, ion implantation is a process in which dopant ions such as boron and arsenic are accelerated by a strong electric field and are then passed through wafer surfaces. Therefore, electrical properties of materials can be modified via such ion implantation.

Ion implantation apparatuses for performing ion implantation methods include a source chamber for generating ions, an analyzer for selecting ions for implantation into a wafer among the generated ions, an acceleration tube for accelerating the selected ions so that the accelerated ions are implanted into the wafer at a desired depth, a beam focusing apparatus for focusing accelerated ion beams, a beam scanning plate for changing the direction of the ion beams to an upward, downward, left or right direction, a neutral beam trap for removing neutral beams included in the ion beams, an implantation chamber for implanting the ions into the wafer, and a vacuum device for providing a vacuum for the previously-mentioned elements. Ion implantation normally causes damage to the lattice structure of the wafer, and to remove the damage, the wafer is normally annealed at an elevated temperature, typically 600 to 1100•.

After the ions (impurities) are implanted into the wafer by the ion implanting apparatus, sheet resistance can be measured in order to estimate whether or not the ions have been properly implanted into the wafer.

The conventional process for wafer implantation typically requires a consistent dose or amount of ions for implantation into the wafer during the implanting process. However, since the process controllability of the implanting process applied in the peripheral annular portion of silicon wafer is inferior to that of the implanting process applied in the central circular portion of silicon wafer, the peripheral annular portion of a silicon wafer exhibits lower performance than the central circular portion of a silicon wafer under same process conditions (such as implanting conditions), thereby reducing the uniformity of electrical properties throughout all portions of the wafer. FIG. 1 illustrates a contour map showing the sheet resistance distribution of a wafer fabricated by the aforementioned conventional implanting process after annealing. The • symbol represents sites having a mean resistivity value of the wafer, and the + and − symbols represent sites for which the resistivity value is above or below the mean value, respectively. As shown in FIG. 1, the wafer has a pattern of non-uniform sheet resistance. FIG. 2 is a schematic diagram illustrating leakage/failure areas 12 and standard areas 14 of a wafer 10 fabricated by the aforementioned conventional implanting process. As shown in FIG. 2, the leakage/failure areas 12 are more frequently observed in the peripheral annular portions of the wafer in comparison with the central circular portions.

Accordingly, implantation processes of a wafer do not result in uniform performances throughout all portions of the wafer. Thus, a need exists to develop new implantation process technology, which results in uniform performances throughout all portions of a wafer, following implantation.

### SUMMARY

The disclosure provides a method for wafer implantation including the following steps: providing a wafer, wherein the wafer comprises a central circular portion, and a peripheral annular portion adjacent to a edge of the wafer, and wherein the central circular portion and the peripheral annular portion are concentric; and implanting ion beams into the wafer, wherein the central circular portion has a first average implantation dose and the peripheral annular portion has a second average implantation dose, and the first average implantation dose and the second first average implantation dose are different. Particularly, the ratio of the first average implantation dose and the second average implantation dose is of between 0.1-0.98 or between 1.02-10.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1 is a contour map showing the sheet resistance distribution of a wafer fabricated by the conventional implanting process.

FIG. 2 is a schematic diagram showing the leakage/failure areas and standard areas of a wafer fabricated by the conventional implanting process;

FIG. 3 is schematic diagram showing a wafer fabricated by the method according to an embodiment of the disclosure;

FIG. 4 is a contour map showing the sheet resistance distribution of the wafer of FIG. 1;

FIG. 5 is a schematic diagram showing the leakage/failure areas and regular areas of a wafer of FIG. 1; and

FIG. 6 is schematic diagram showing a wafer fabricated by the method according to another embodiment of the disclosure.

### DETAILED DESCRIPTION

The following description is of the best-contemplated mode of carrying out the disclosure. This description is made for the purpose of illustrating the general principles of the disclosure and should not be taken in a limiting sense. The scope of the disclosure is best determined by reference to the appended claims.

The disclosure provides a method for wafer implantation, wherein the method includes the following steps. First, a wafer including a central circular portion, and a peripheral annular portion is provided, wherein the central circular portion and the peripheral annular portion are concentric. Next, the wafer is implanted by ion beams such that the central circular portion has a first average implantation dose and the peripheral annular portion has a second average implantation dose, wherein the first average implantation dose and the second first average implantation dose are different. The ion beams can include impurities to produce n or p type doped regions on the wafer 100, wherein the impurities can include antimony, arsenic or phosphorus to produce the n type doped regions, or include boron, gallium or indium to produce the p type doped regions on the wafer.

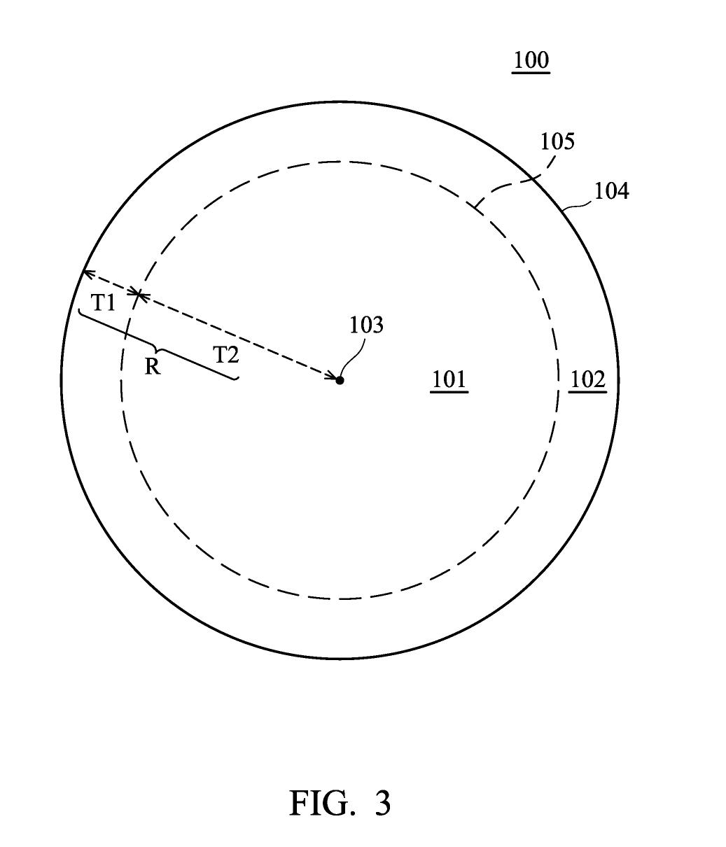

According to an embodiment of the invention, as shown in FIG. 3, the wafer 100 (such as a silicon wafer) includes a central circular portion 101 and a peripheral annular portion 102, wherein the central circular portion 101 includes the center 103 of the wafer 100, and the peripheral annular portion 102 is adjacent to the edge 104 of the wafer 100, and a boundary 105 is defined between the central circular portion 101 and the peripheral annular portion 102. One key aspect of the disclosure is that the central circular portion 101 has a first average implantation dose D1 and the peripheral annular portion has a second average implantation dose D2, after implanting of ion beams into the wafer 100. Particularly, the first average implantation dose D1 is not equal to the second average implantation dose D2. The ratio of the first average implantation dose D1 and the second average implantation dose D2 can be of between 0.1-0.98 or between 1.02-10. Namely, the first average implantation dose D1 can be less or larger than the second average implantation dose D2.

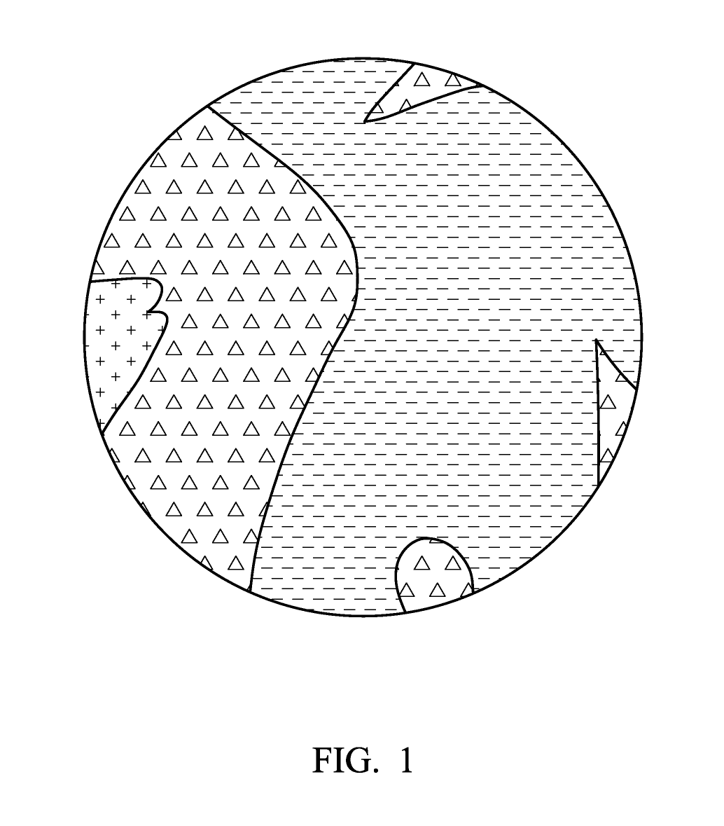

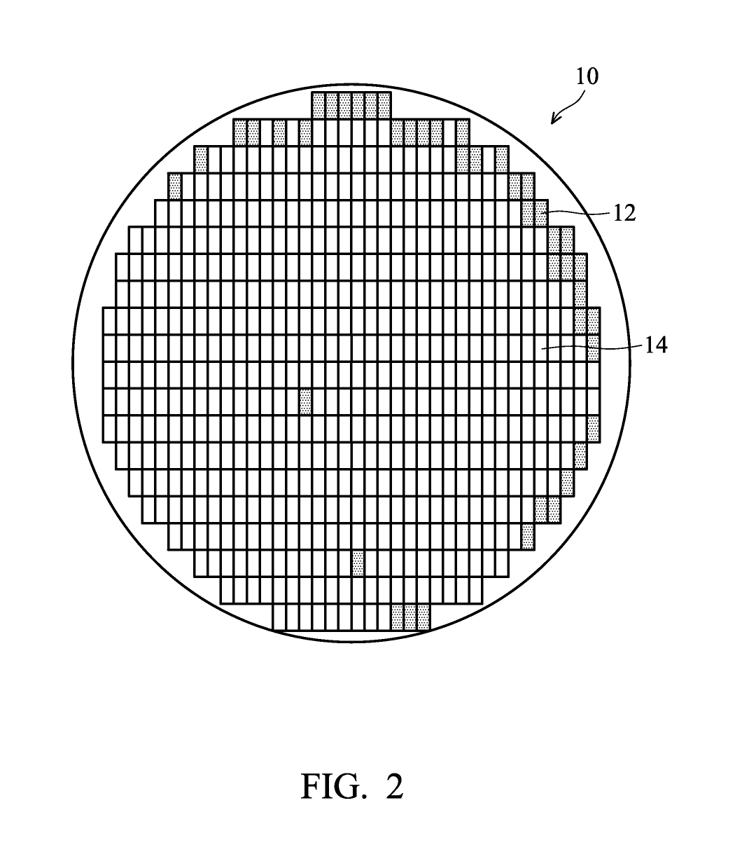

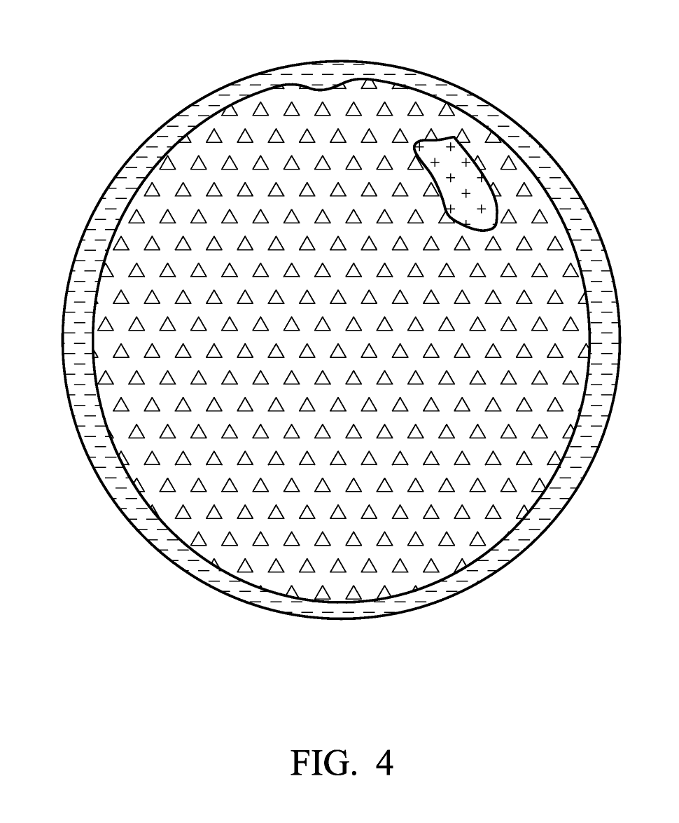

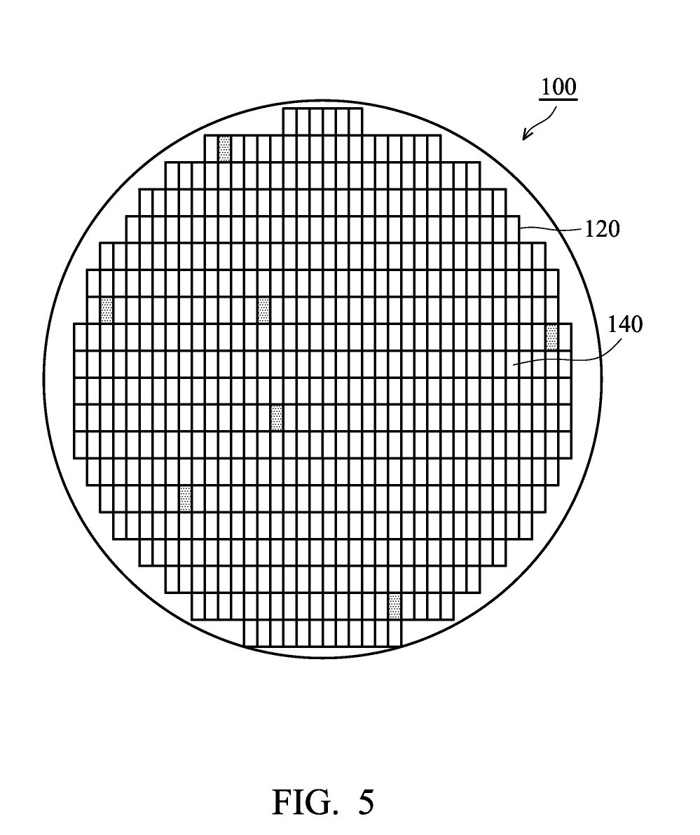

In this embodiment, the implantation dose of the central circular portion 101 can be a fixed value equal to the set dose of the specific implanting process, since the central circular portion 101 exhibits good process controllability for implanting. Further, the set dose of the specific implanting process is optionally increased or reduced for the implanting dose of the peripheral annular portion 102 according to the process controllability of the peripheral annular portion 102. Therefore, the first average implantation dose D1 is not equal to the second average implantation dose D2 in order to achieve uniformity of electrical properties throughout all portions of the wafer 100 without degrading the performance of the central circular portion 101 of the wafer. FIG. 4 illustrates a contour map showing the sheet resistance distribution of the wafer 100 of FIG. 3 after annealing. The • symbol represents sites having a mean resistivity value of the wafer, and the + and − symbols represent sites for which the resistivity value is above and below the mean value, respectively. As shown in FIG. 4, the sheet resistance of the wafer 100 is more uniform than that of the wafer shown in FIG. 1, thereby, the uniformity of the wafer 100 can be improved. FIG. 5 is a schematic diagram illustrating leakage/failure areas 120 and standard areas 140 of the wafer 100 of FIG. 3. As shown in FIG. 5, the total amounts of the leakage/failure areas 120 of the wafer 100 are reduced, and the leakage/failure areas 120 observed in the central circular portion 101 are also greatly reduced in comparison with FIG. 2, thereby the current leakage characteristics can be improved. Accordingly, the performance of the peripheral annular portion 102 is improved, enhancing uniformity and yield of subsequently processed semiconductors.

In an embodiment of the disclosure, still referring to FIG. 3, the minimum distance T1 between the edge 104 of the wafer and the boundary 105 between the central circular portion 101 and the peripheral annular portion 102 can be equal to or less than the minimum distance T2 from the center 103 to the boundary 105. Namely, the sum of the minimum distance T1 and the minimum distance T2 is equal to the radius R of the wafer 100, and the minimum distance T1 can be not more than a half of the radius R of the wafer 100. In some embodiments of the disclosure, the minimum distance T1 can be not more than a quarter of the radius R of the wafer 100. Further, the minimum distance T1 can not be more than a tenth of the radius R of the wafer 100.

In an embodiment of the disclosure, the implantation dose of the wafer 100 can be gradually increased from the edge 104 to the center 103 of the wafer 100 or from the center 103 to the edge 104 of the wafer 100. In some embodiments of the disclosure, the implantation dose of the central circular portion 101 of the wafer 100 can be a fixed value, and/or the implantation dose of the peripheral annular portion 102 of the wafer 100 can a fixed value. Further, the implantation dose of the central circular portion 101 can be gradually increased or reduced from the edge 104 to the center 103 of the wafer 100, and the implantation dose of the peripheral annular portion 102 can be gradually increased or reduced from the edge 104 to the center 103 of the wafer 100.

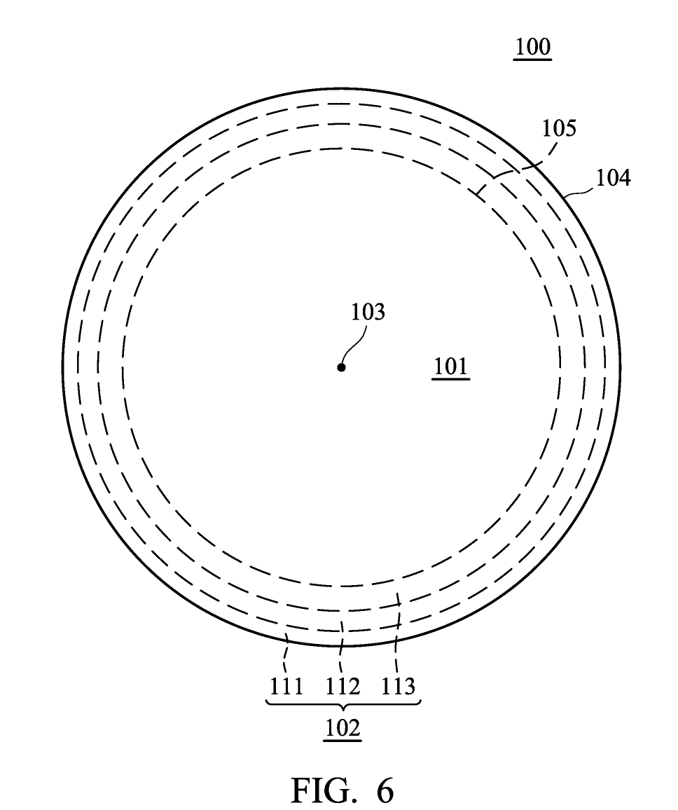

FIG. 6 shows a wafer 200 fabricated by the method according to another embodiment of the disclosure, wherein the peripheral annular portion 101 further includes a plurality of annular sub-portions, such as a first annular sub-portion 111, a second annular sub-portion 112, and a third annular sub-portion 113. Particularly, each annular sub-portion can have a fixed implantation dose or a gradually changing implantation dose, and the average implantation doses of the annular sub-portions 111, 112, and 113 can be different.

Accordingly, the method for wafer implantation of the disclosure can be used to ensure uniformity of performance without degrading the performance of the central circular portion 101 of the wafer and improve the yield of subsequently processed semiconductors.

While the disclosure has been described by way of example and in terms of the preferred embodiments, it is to be understood that the disclosure is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for wafer implantation, comprising:
providing a wafer, wherein the wafer comprises a central circular portion, and a peripheral annular portion adjacent to a edge of the wafer, and wherein the central circular portion and the peripheral annular portion are concentric; and
implanting ion beams into the wafer, wherein the central circular portion has a first average implantation dose and the peripheral annular portion has a second average implantation dose, and the first average implantation dose and the second first average implantation dose are different.

2. The method as claimed in claim 1, wherein the minimum distance between the edge of the wafer and a boundary between the central circular portion and the peripheral annular portion is not more than a half of the radius of the wafer.

3. The method as claimed in claim 1, wherein the minimum distance between the edge of the wafer and a boundary between the central circular portion and the peripheral annular portion is not more than a quarter of the radius of the wafer.

4. The method as claimed in claim 1, wherein the minimum distance between the edge of the wafer and a boundary between the central circular portion and the peripheral annular portion is not more than a tenth of the radius of the wafer.

5. The method as claimed in claim 1, wherein the implantation dose of the wafer is gradually increased from the edge to the center of the wafer.

6. The method as claimed in claim 1, wherein the implantation dose of the wafer is gradually reduced from the edge to the center of the wafer.

7. The method as claimed in claim 1, wherein the implantation dose of the central circular portion of the wafer is a fixed value.

8. The method as claimed in claim 1, wherein the implantation dose of the peripheral annular portion of the wafer is a fixed value.

9. The method as claimed in claim 1, wherein the implantation dose of the central circular portion is gradually increased from the edge to the center of the wafer.

10. The method as claimed in claim 1, wherein the implantation dose of the central circular portion is gradually reduced from the edge to the center of the wafer.

11. The method as claimed in claim 1, wherein the implantation dose of the peripheral annular portion is gradually increased from the edge to the center of the wafer.

12. The method as claimed in claim 1, wherein the implantation dose of the peripheral annular portion is gradually reduced from the edge to the center of the wafer.

13. The method as claimed in claim 1, wherein the peripheral annular portion comprises a plurality of annular sub-portions, and where the annular sub-portions are concentric.

14. The method as claimed in claim 13, wherein each of the annular sub-portions has a fixed implantation dose, and the fixed implantation doses of the annular sub-portions are different.

15. The method as claimed in claim 1, wherein the first average implantation dose is larger than the second average implantation dose.

16. The method as claimed in claim 1, wherein the first average implantation dose is less than the second average implantation dose.

17. The method as claimed in claim 1, wherein the ratio of the first average implantation dose and the second average implantation dose is of between 0.1-0.98 or 1.02-10.

18. The method as claimed in claim 1, wherein the ion beams comprises impurities to produce n or p type doped regions on the wafer.

19. The method as claimed in claim 1, wherein the impurities comprises antimony, arsenic or phosphorus to produce the n type doped regions on the wafer.

20. The method as claimed in claim 1, wherein the impurities comprise boron, gallium or indium to produce the p type doped regions on the wafer.
